(19) United States
(12) Patent Application Publication
(10) Pub. No.: US 2025/0374463 A1
(43) Pub. Date: Dec. 4, 2025

(54) ETCHING SYSTEM, ETCHING METHOD USING THE ETCHING SYSTEM, AND ELECTRONIC DEIVCE

(71) Applicant: Samsung Display Co., Ltd., Yongin-si (KR)

(72) Inventors: Byoung Yul SHIM, Yongin-si (KR); Dong Ho KIM, Yongin-si (KR); Hyun Chul KIM, Yongin-si (KR); Dong Cheon SHIN, Yongin-si (KR); Ju Suk OH, Yongin-si (KR); Kang Duk CHOI, Yongin-si (KR); Seung Pyo HONG, Yongin-si (KR)

(21) Appl. No.: 19/196,003

(22) Filed: May 1, 2025

(30) Foreign Application Priority Data
May 31, 2024 (KR) 10-2024-0071534

(51) Int. Cl. H05K 5/03; C03C 15/00

(52) U.S. Cl. CPC H05K 5/03; C03C 15/00

(57) ABSTRACT

An etching system and an etching method using the etching system are disclosed. The etching system may include an etching target including a first etching protection area, a second etching protection area, and an etching target area between the first etching protection area and the second etching protection area, a nozzle to provide an etching material toward the etching targe, a first etching area selection portion which is between the etching target and the nozzle and overlaps the first etching protection area in plan view, and a second etching area selection portion which is between the etching target and the nozzle and overlaps the second etching protection area in plan view. The first etching area selection portion and the second etching area selection portion may be provided to be relatively movable in a direction away from each other.

### CROSS-REFERENCE TO RELATED APPLICATION

The present application claims priority to and the benefit of Korean Patent Application No. 10-2024-0071534, filed on May 31, 2024, in the Korean Intellectual Property Office, the entire content of which is incorporated herein by reference.

### BACKGROUND

### 1. Field

One or more embodiments of the present disclosure relate to an etching system, an etching method using the etching system, and an electronic device.

### 2. Description of the Related Art

Foldable display devices may be folded and unfolded like (similarly to) a book. These foldable display devices offer the advantage (feature) of being compact and/or portable when folded, and providing a wide screen for the user when unfolded.

### SUMMARY

A cover window of (constituting) a foldable display device may have a relatively thin thickness in one or more areas such that an operation of folding and unfolding the display device may be performed smoothly.

One or more aspects of embodiments of the present disclosure are directed toward an etching system to effectively or suitably provide the above-described cover window and/or the like and an etching method using the etching system.

Additional aspects will be set forth in part in the description which follows and, in part, will be apparent from the description, or may be learned by practice of the presented embodiments of the disclosure.

An etching system according to one or more embodiments of the present disclosure includes an etching target including a first etching protection area, a second etching protection area, and an etching target area between the first etching protection area and the second etching protection area, a nozzle to provide an etching material toward the etching target, a first etching area selection portion which is between the etching target and the nozzle and overlaps the first etching protection area in plan view and a second etching area selection portion which is between the etching target and the nozzle and overlaps the second etching protection area in plan view, wherein the first etching area selection portion and the second etching area selection portion are relatively movable in a direction away from each other

In one or more embodiments, the etching target area may not overlap the first etching area selection portion and the second etching area selection portion in plan view.

In one or more embodiments, the first etching area selection portion may be in contact with the etching target at a boundary between the first etching protection area and the etching target area, and the second etching area selection portion may be in contact with the etching target at a boundary between the second etching protection area and the etching target area.

In one or more embodiments, the first etching area selection portion may include a 1-1 fastening portion and a 1-2 fastening portion, a first etching material blocking film having one end fastened to the 1-1 fastening portion and the other end fastened to the 1-2 fastening portion, and a first pressing member to press the first etching material blocking film between the one end and the other end of the first etching material blocking film.

In one or more embodiments, in plan view, the first pressing member may be closer to the etching target area than the 1-1 fastening portion and the 1-2 fastening portion are each to the etching target area.

In one or more embodiments, the second etching area selection portion may include a 2-1 fastening portion and a 2-2 fastening portion, a second etching material blocking film having one end fastened to the 2-1 fastening portion and the other end fastened to the 2-2 fastening portion, and a second pressing member to press the second etching material blocking film between the one end and the other end of the second etching material blocking film.

In one or more embodiments, in plan view, the second pressing member may be closer to the etching target area than the 2-1 fastening portion and the 2-2 fastening portion are each to the etching target area.

In one or more embodiments, each of the first pressing member and the second pressing member may extend in a first direction.

In one or more embodiments, each of the first pressing member and the second pressing member may include a roller to rotate about the first direction as a rotation axis.

In one or more embodiments, the first etching material blocking film may overlap the first etching protection area in plan view, and the second etching material blocking film may overlap the second etching protection area in plan view.

In one or more embodiments, the first etching material blocking film may not overlap the second etching protection area and the etching target area in plan view, and the second etching material blocking film may not overlap the first etching protection area and the etching target area in plan view.

An etching method using an etching system according to one or more embodiments is provided. The etching system includes an etching target including a first etching protection area, a second etching protection area, and an etching target area between the first etching protection area and the second etching protection area, a nozzle to provide an etching material toward the etching target, a first etching area selection portion which is between the etching target and the nozzle and overlaps the first etching protection area in plan view, and a second etching area selection portion which is between the etching target and the nozzle and overlaps the second etching protection area in plan view. The etching method includes providing the etching material from the nozzle and concurrently (e.g., simultaneously) and relatively moving the first etching area selection portion and the second etching area selection portion in a direction away from each other.

In one or more embodiments, as the first etching area selection portion and the second etching area selection portion relatively move in the direction away from each other, an area of the etching target area may increase.

In one or more embodiments, as the first etching area selection portion and the second etching area selection portion relatively move in the direction away from each other, an area of each of the first etching protection area and the second etching protection area may decrease.

In one or more embodiments, in the relatively moving of the first etching area selection portion and the second etching area selection portion in the direction away from each other, an amount of change in separation distance between the first etching area selection portion and the second etching area selection portion per unit time may be constant (e.g., substantially constant).

In one or more embodiments, in the relatively moving of the first etching area selection portion and the second etching area selection portion in the direction away from each other, an amount of change in separation distance between the first etching area selection portion and the second etching area selection portion per unit time may gradually increase.

In one or more embodiments, in the relatively moving of the first etching area selection portion and the second etching area selection portion in the direction away from each other, an amount of change in separation distance between the first etching area selection portion and the second etching area selection portion per unit time may gradually decrease.

In one or more embodiments, in the relatively moving of the first etching area selection portion and the second etching area selection portion in the direction away from each other, an amount of change in separation distance between the first etching area selection portion and the second etching area selection portion per unit time may gradually decrease and then gradually increase.

In one or more embodiments, in the relatively moving of the first etching area selection portion and the second etching area selection portion in the direction away from each other, the first etching area selection portion may be in contact with the etching target at a boundary between the first etching protection area and the etching target area, and the second etching area selection portion may be in contact with the etching target at a boundary between the second etching protection area and the etching target area.

An electronic device according to one or more embodiments is provided. The electronic device includes a processor to provide an input image data, and a display device to display an image based on the input image data and including a cover window. The cover window includes a first non-foldable area, a second non-foldable area, and a foldable area between the first non-foldable area and the second non-foldable area. The foldable area includes a central foldable area, a first in-between foldable area between the central foldable area and the first non-foldable area, and a second in-between foldable area between the central foldable area and the second non-foldable area. The cover window is manufactured according to the etching method utilizing the etching system as described in one or more embodiments.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1 and 2 each is a view illustrating a cover window for a foldable display device.

FIGS. 3A and 3B each is a view illustrating a foldable display device including the cover window of FIGS. 1 and 2.

FIG. 4 is plan view illustrating an etching system according to one or more embodiments of the present disclosure.

FIG. 5 is a cross-sectional view taken along the line 11-11′ of FIG. 4.

FIGS. 6-10 are views illustrating an etching method using the etching system of FIG. 4.

FIGS. 11 and 12 are a graph and a view, respectively, illustrating a first application example of an etching method of the present disclosure.

FIGS. 13 and 14 are a graph and a view, respectively, a second application example of an etching method of the present disclosure.

FIGS. 15 and 16 are a graph and a view, respectively, illustrating a third application example of an etching method of the present disclosure.

FIGS. 17 and 18 are a graph and a view, respectively, illustrating a fourth application example of an etching method of the present disclosure.

FIG. 19 is a schematic block diagram illustrating an electronic device including a display device according to one or more embodiments.

FIG. 20 is a schematic diagram illustrating an example where the electronic device of FIG. 19 is a smartphone.

FIG. 21 is a schematic diagram illustrating an example where the electronic device of FIG. 19 is a tablet computer.

### DETAILED DESCRIPTION

Hereinafter, the subject matter of the present disclosure will be described in more detail with reference to the accompanying drawings. In the following description, it should be noted that only portions desired or required for comprehension of operations according to the present disclosure will be described, and descriptions of other portions will not be provided not to make subject matters of the present disclosure obscure. In addition, the present disclosure is not limited to the following described embodiments but may also be embodied in one or more suitable forms. Rather, these embodiments are provided as examples so that this disclosure will be thorough and complete and will fully convey the aspects and features of the present disclosure to those skilled in the art.

Throughout the specification, It will be understood that if (e.g., when) an element is referred to as being “on”, “coupled to” or “connected to” another element, it can be directly coupled or connected to the other element or intervening elements may be present therebetween. In contrast, if (e.g., when) an element is referred to as being “directly on”, “directly coupled to” or “directly connected to” another element, there are no intervening elements present.

The terminology used herein is for the purpose of describing specific embodiments and is not intended to limit the present disclosure. Throughout the specification, unless explicitly described to the contrary, the word “include” and variations, such as “includes” or “including,” will be understood to imply the inclusion of stated elements but not the exclusion of any other elements. “At least any one of X, Y, and Z” and “at least one selected from among the array consisting of X, Y, and Z” may be construed as each of X, Y, and Z and/or a (e.g., any suitable) combination of two or more of X, Y, and Z (for example, XYZ, XYY, YZ, and ZZ). As used herein, “and/or” includes one or more combinations of corresponding components.

It will be understood that, although the terms “first”, “second”, “third”, and so on may be used herein to describe one or more suitable elements, these elements are not limited by these terms. These terms are used to distinguish one element from another element. Thus, a first element described in more detail could also be termed as a second or third element without departing from the spirit and scope of the present disclosure.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned over, elements described as “below” or “beneath” other elements or features may then be oriented “above” the other elements or features. Thus, in one or more embodiments, the example term “below” may encompass both (e.g., simultaneously) an orientation of above and below. Furthermore, the device may be otherwise oriented (e.g., rotated 90 degrees or at other orientations), and, as such, the spatially relative descriptors used herein may be interpreted accordingly.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

One or more embodiments are described with reference to drawings that schematically illustrate ideal embodiments. Accordingly, it will be understood that the shapes may vary depending, for example, on tolerances and/or manufacturing techniques. Accordingly, one or more embodiments disclosed herein should not be construed as being limited to the specific shapes shown herein, but should be construed to include deviations in shapes that result from, for instance, manufacturing. As such, the shapes shown in the drawings may not depict the actual shapes of regions of the device, and embodiments of the present disclosure are not limited thereto.

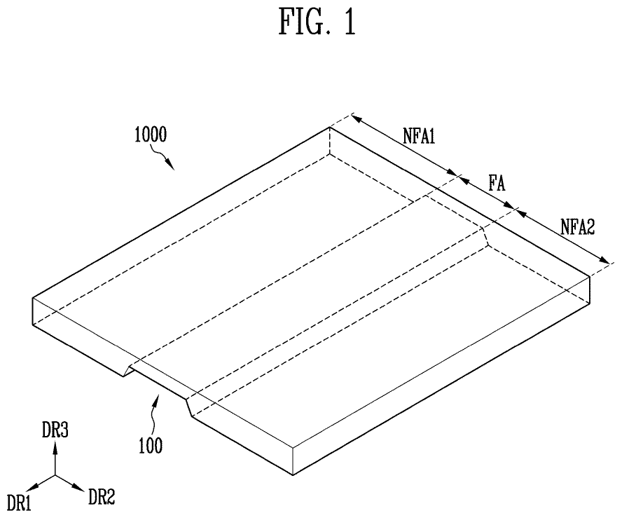

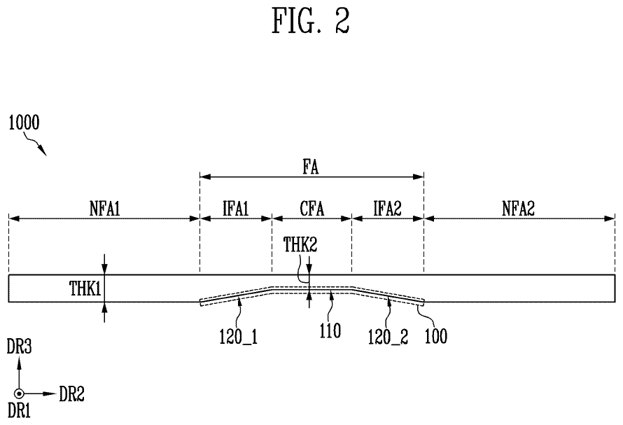

FIGS. 1 and 2 each is a view illustrating a cover window for a foldable display device.

Referring to FIG. 1, a cover window 1000 may include a first non-foldable area NFA1, a second non-foldable area NFA2, and/or a foldable area FA between the first non-foldable area NFA1 and the second non-foldable area NFA2.

The cover window 1000 may be provided to be foldable and non-foldable like a book. The foldable area FA may be an area about which the cover window 1000 is folded and unfolded. In contrast, the first non-foldable area NFA1 and the second non-foldable area NFA2 may be areas in which there is substantially no folding or unfolding.

A groove 100 formed or provided in a first direction DR1 may be defined in the foldable area FA. With respect to the groove 100, the second non-foldable area NFA2 may be spaced and/or apart (e.g., spaced apart or separated) from the first non-foldable area NFA1 in a second direction DR2 intersecting the first direction DR1. Because the groove 100 is defined, a thickness of the foldable area FA in a third direction DR3 may become relatively thinner. Here, the third direction DR3 may be normal (e.g., substantially perpendicular) to the first direction DR1 and the second direction DR2. In one or more embodiments, the flexibility of the cover window 1000 in the foldable area FA may be improved or enhanced.

Referring to FIG. 2, a thickness of each of the first non-foldable area NFA1 and the second non-foldable area NFA2 in the third direction DR3 may be substantially constant. For example, the thickness of each of the first non-foldable area NFA1 and the second non-foldable area NFA2 in the third direction DR3 may be a first thickness THK1.

The foldable area FA may include a central foldable area CFA, a first in-between foldable area IFA1 between the central foldable area CFA and the first non-foldable area NFA1 and a second in-between foldable area IFA2 between the central foldable area CFA and the second non-foldable area NFA2.

A thickness of the central foldable area CFA in the third direction DR3 may be substantially constant. For example, the thickness of the central foldable area CFA in the third direction DR3 may be a second thickness THK2. The second thickness THK2 may be less than the first thickness THK1. In one or more embodiments, one surface 110 of the central foldable area CFA constituting the groove 100 may be substantially flat.

A thickness of the first in-between foldable area IFA1 in the third direction DR3 may gradually increase from the central foldable area CFA to the first non-foldable area NFA1. For example, as shown in FIG. 2, the thickness of the first in-between foldable area IFA1 in the third direction DR3 may increase linearly (e.g., substantially linearly) from the central foldable area CFA to the first non-foldable area NFA1. In one or more embodiments, one surface 120_1 of the first in-between foldable area IFA1 constituting the groove 100 may be provided as an inclined surface having a constant (e.g., substantially constant) inclination. However, one surface 120_1 of the first in-between foldable area IFA1 is not limited to that described above. One surface 120_1 of the first in-between foldable area IFA1 may be provided as an inclined surface, but the inclination thereof may be changed.

A thickness of the second in-between foldable area IFA2 in the third direction DR3 may gradually increase from the central foldable area CFA to the second non-foldable area NFA2. For example, as shown in FIG. 2, the thickness of the second in-between foldable area IFA2 in the third direction DR3 may increase linearly (e.g., substantially linearly) from the central foldable area CFA to the second non-foldable area NFA2. In one or more embodiments, one surface 120_2 of the second in-between foldable area IFA2 constituting the groove 100 may be provided as an inclined surface having a constant (e.g., substantially constant) inclination. However, one surface 120_2 of the second in-between foldable area IFA2 is not limited to that described above. One surface 120_2 of the second in-between foldable area IFA2 may be provided as an inclined surface, but the inclination thereof may be changed.

As described above, the thickness of each of the first in-between foldable area IFA1 and the second in-between foldable area IFA2 in the third direction DR3 may be greater than the second thickness THK2 (see FIG. 2) of the central foldable area CFA. In one or more embodiments, the cover window 1000 may not only secure sufficient or suitable flexibility in the foldable area FA, but also may further secure a function of improving or enhancing impact resistance strength at a certain level or more and reducing distortion.

In one or more embodiments, one surface 120_1 of the first in-between foldable area IFA1 may be symmetrical (e.g., substantially symmetrical) with one surface 120_2 of the second in-between foldable area IFA2 with respect to the central foldable area CFA.

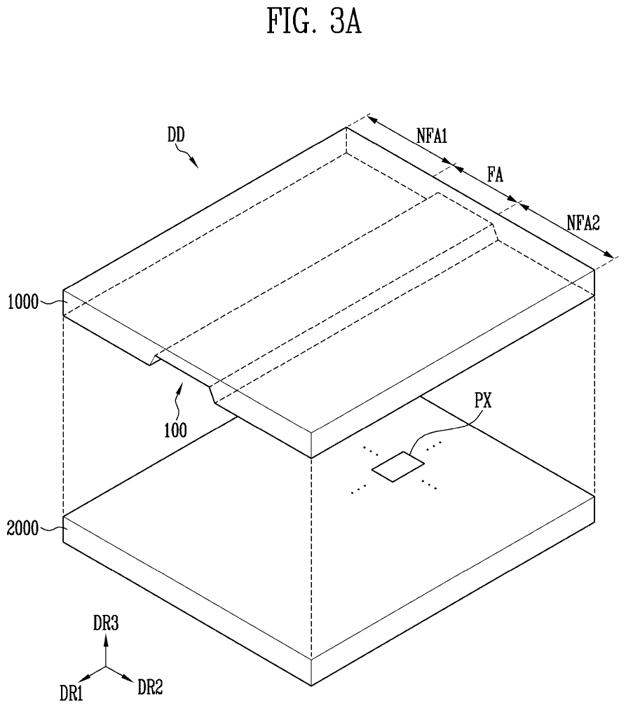

FIGS. 3A and 3B each is a view illustrating a foldable display device including the cover window of FIGS. 1 and 2.

Referring to FIG. 3A, a foldable display device DD may include the cover window 1000 and/or a display panel 2000.

The display panel 2000 may include a plurality of pixels PX. Each of the plurality of pixels PX may generate light. The display panel 2000 may display an image (or a video) by combining light emitted from the plurality of pixels PX.

The cover window 1000 may be attached onto or coupled to the display panel 2000. A groove 100 defined in the cover window 1000 may be in a direction facing the display panel 2000. In the present context, a groove 100 defined in the cover window 1000 may be formed in a direction facing the display panel 2000, and it refers to that the groove may be oriented such that its lowest point (the bottom or valley) is directed towards the display panel (e.g., a line drawn from the deepest part of the groove may point towards the display panel.) The cover window 1000 may be provided to be substantially transparent to transmit light emitted from the plurality of pixels PX. For example, the cover window 1000 may include glass.

In the foldable area FA, the foldable display device DD may be folded and unfolded like a book. In the display panel 2000, the plurality of pixels PX may be provided entirely (e.g., substantially entirely) in areas overlapping the first non-foldable area NFA1, the second non-foldable area NFA2, and/or the foldable area FA. In one or more embodiments, a user of the display device DD may view an image (or a video) not only in the first non-foldable area NFA1 and the second non-foldable area NFA2, but also in the foldable area FA.

In one or more embodiments, as described with reference to FIGS. 1 and 2, the cover window 1000 of the present disclosure may have sufficient or suitable flexibility, impact resistance strength at a certain level or more, and a distortion reduction function. In one or more embodiments, the foldable display device DD including the cover window 1000 may have excellent or suitable durability and excellent or suitable display quality.

Referring to FIG. 3B, a foldable display device DD shown in FIG. 3B may be substantially the same as the foldable display device DD described with reference to FIG. 3A, except that the groove 100 defined in the cover window 1000 may be to face in the third direction DR3. That is, a groove 100 defined in the cover window 1000 may face in a direction away from the display panel 2000. In this context, a groove 100 defined in the cover window 1000 may be formed in a direction facing away from the display panel 2000, and it refers to that the groove may be oriented such that its lowest point (the bottom or valley) is directed away from the display panel (e.g., a line drawn from the deepest part of the groove may point away from the display panel). Therefore, redundant descriptions will not be provided.

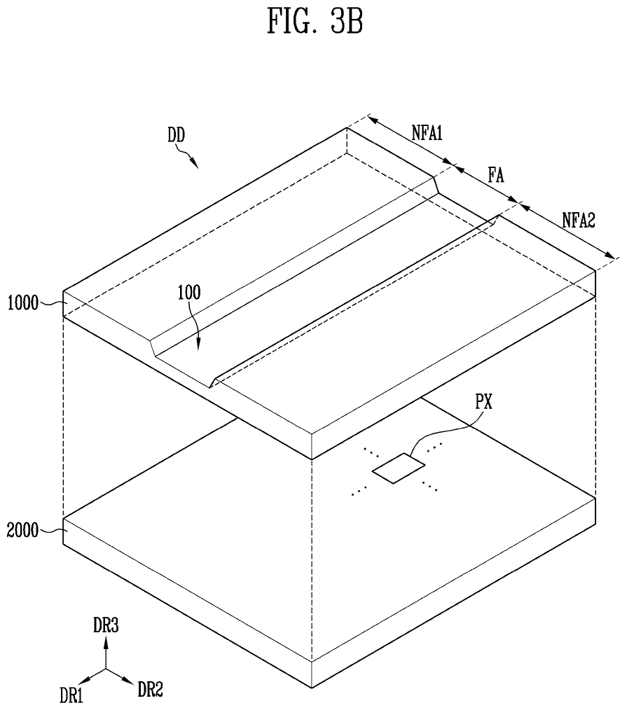

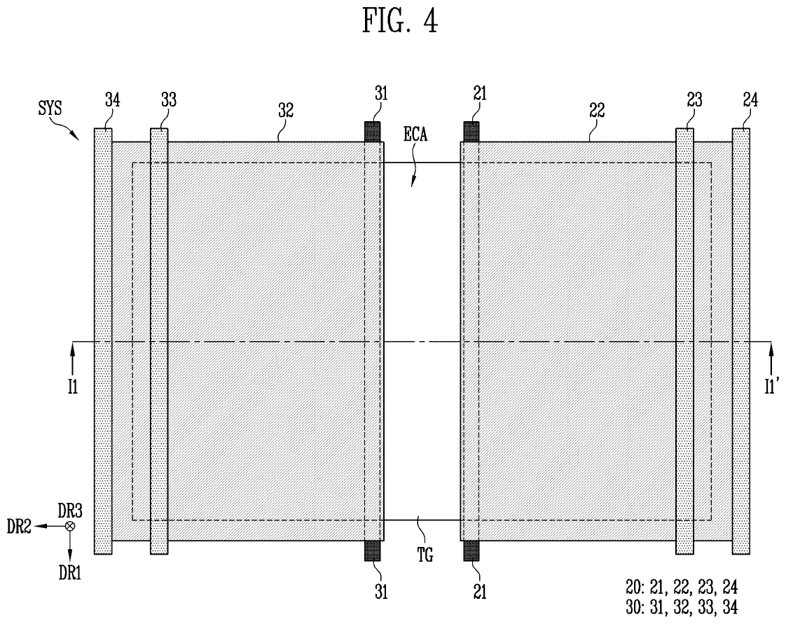

FIG. 4 is plan view illustrating an etching system according to one or more embodiments of the present disclosure. FIG. 5 is a cross-sectional view taken along the line 11-11′ of FIG. 4.

Referring to FIGS. 4 and 5, an etching system SYS may include an etching target TG, a nozzle NZ, a first etching area selection portion 20, and/or a second etching area selection portion 30.

For example, the etching target TG may be glass to manufacture the cover window 1000 described with reference to FIGS. 1 and 2. In one or more embodiments, the etching target TG may include the first non-foldable area NFA1 and the second non-foldable area NFA2 described with reference to FIG. 2 and the foldable areas FA between the first non-foldable area NFA1 and the second non-foldable area NFA2. The foldable area FA may include the central foldable area CFA, the first in-between foldable area IFA1, and the second in-between foldable area IFA2.

In FIG. 5, the etching target TG before an etching method using the etching system SYS is performed is illustrated. In one or more embodiments, the groove 100 described with reference to FIGS. 1 and 2 may not be in the etching target TG. Each of the upper surface and the lower surface of the etching target TG may be substantially flat, and a thickness of the etching target TG in a third direction DR3 may be substantially constant.

The nozzle NZ may be above the etching target TG. The nozzle NZ may be to provide an etching material toward the etching target TG. For example, if (e.g., when) the etching target TG is glass to manufacture the cover window 1000, the etching material may be an etchant to etch the glass. In one or more embodiments, a portion of the glass that is in contact with the etchant may be etched and removed.

The first etching area selection portion 20 and/or the second etching area selection portion 30 may be between the etching target TG and the nozzle NZ. The first etching area selection portion 20 and the second etching area selection portion 30 may be spaced and/or apart (e.g., spaced apart or separated) from each other.

As shown in FIG. 4, in plan view, first etching area selection portion 20 and the second etching area selection portion 30 may overlap one or more areas of the etching target TG.

In plan view, an area of the etching target TG that overlaps the first etching area selection portion 20 may be referred to as a first etching protection area. For example, the first etching area selection portion 20 may overlap the first in-between foldable area IFA1 and the first non-foldable area NFA1 of the etching target TG. In one or more embodiments, the first in-between foldable area IFA1 and the first non-foldable area NFA1 may be referred to as a first etching protection area.

In plan view, an area of the etching target TG that overlaps the second etching area selection portion 30 may be referred to as a second etching protection area. For example, the second etching area selection portion 30 may overlap the second in-between foldable area IFA2 and the second non-foldable area NFA2 of the etching target TG. In one or more embodiments, the second in-between foldable area IFA2 and the second non-foldable area NFA2 may be referred to as a second etching protection area.

In plan view, an area of the etching target TG that does not overlap the first etching area selection portion 20 and the second etching area selection portion 30 may be referred to as an etching target area ECA. For example, the first etching area selection portion 20 and the second etching area selection portion 30 may not overlap the central foldable area CFA of the etching target TG. In one or more embodiments, the central foldable area CFA may be referred to as the etching target area ECA.

The etching material provided from the nozzle NZ may be blocked by the first etching area selection portion 20 and the second etching area selection portion 30. Therefore, if (e.g., when) the first etching area selection portion 20 and the second etching area selection portion 30 are provided as shown in FIGS. 4 and 5, the etching material may not be substantially provided to the first in-between foldable area IFA1, the second in-between foldable area IFA2, the first non-foldable area NFA1, and/or the second non-foldable area NFA2 which are the first etch protection area and the second etch protection area. In one or more embodiments, the etching target TG may not be substantially etched in the first in-between foldable area IFA1, the second in-between foldable area IFA2, the first non-foldable area NFA1, and/or the second non-foldable area NFA2. In contrast, the etching material provided from the nozzle NZ may be provided to the etching target area ECA of the etching target TG. In one or more embodiments, the etching target area ECA of the etching target TG may be etched by the etching material.

In this way, the first etching area selection portion 20 and the second etching area selection portion 30 may selectively block the etching material provided from the nozzle NZ, thereby acting or serving to allow the etching material to be provided only to the etching target area ECA of the etching target TG.

In one or more embodiments, the first etching area selection portion 20 and the second etching area selection portion 30 may be relatively movable in a direction away from each other. In the context of the present disclosure, “relatively movable” refers to that the first etching area selection portion 20 and the second etching area selection portion 30 may move in relation to each other. This movement may allow them to suitably adjust their positions independently, for example, in opposite directions, to achieve the desired configuration or arrangement for the etching process. This relative movement may ensure that the etching material may be substantially precisely directed to the target area while protecting the surrounding areas. For example, while the etching material is being supplied or provided from the nozzle NZ, the first etching area selection portion 20 and the second etching area selection portion 30 may be relatively moved in a direction away from each other to increase an area of the etching target area ECA. In one or more embodiments, a structure of the groove 100 having a different thickness for each area as described with reference to FIG. 2 may be formed or provided.

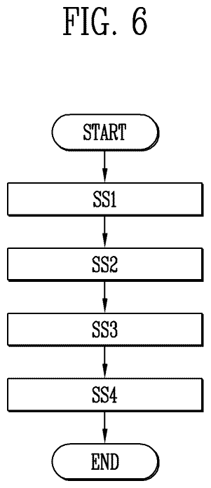

In FIG. 5, the first etching area selection portion 20 and the second etching area selection portion 30 are shown as being spaced and/or apart (e.g., spaced apart or separated) from the etching target TG, but embodiments of the present disclosure are not limited thereto. The first etching area selection portion 20 and the second etching area selection portion 30 may be provided in contact with at least a portion of the etching target TG. For example, the first etching area selection portion 20 and the second etching area selection portion 30 may be provided to relatively move in a direction toward the etching target TG. In one or more embodiments, for example, the first etching area selection portion 20 may be in contact with the etching target TG at a boundary between the etching target area ECA and the first etching protection area (for example, IFA1 and NFA1), and the second etching area selection portion 30 may be in contact with the etching target TG at a boundary between the etching target area ECA and the second etching protection area (for example, IFA2 and NFA2). Such one or more embodiments will be described in more detail with reference to FIG. 7.

In one or more embodiments, the first etching area selection portion 20 may include a first pressing member 21, a first etching material blocking film 22, a 1-1 fastening portion 23, and/or a 1-2 fastening portion 24.

The first etching material blocking film 22 may not be etched by the etching material sprayed from the nozzle NZ. In one or more embodiments, the first etching material blocking film 22 may act or serve to block the etching material.

One end of the first etching material blocking film 22 may be fastened to the 1-1 fastening portion 23, and the other end thereof may be fastened to the 1-2 fastening portion 24. The first pressing member 21 may be to press the first etching material blocking film 22 between one end and the other end of the first etching material blocking film 22. In one or more embodiments, the 1-1 fastening portion 23 and the 1-2 fastening portion 24 may act or serve to tightly pull the first etching material blocking film 22 and maintain the tension of the first etching material blocking film 22.

The first pressing member 21 may be closer to the etching target area ECA than the 1-1 fastening portion 23 and the 1-2 fastening portion 24 are each to the etching target area ECA. In one or more embodiments, the first etching material blocking film 22 may be provided to overlap the first etching protection area (for example, IFA1 and NFA1) in plan view. The first etching material blocking film 22 may be provided not to overlap the second etching protection area (for example, IFA2 and NFA2) and the etching target area ECA in plan view.

The first pressing member 21 may relatively move in a direction toward the etching target TG. The first pressing member 21 may relatively move in a direction away from the second etching area selection portion 30. In this way, the first pressing member 21 may be provided to move in one or more suitable directions.

The first pressing member 21 may extend in a first direction DR1. According to one or more embodiments, the first pressing member 21 may include a roller to rotate about the first direction DR1 as a rotation axis. In one or more embodiments, friction between the first pressing member 21 and the first etching material blocking film 22 may be minimized or reduced if (e.g., when) the first pressing member 21 moves in one or more suitable directions.

In one or more embodiments, the second etching area selection portion 30 may be provided to be substantially similar to the first etching area selection portion 20. The second etching area selection portion 30 may include a second pressing member 31, a second etching material blocking film 32, a 2-1 fastening portion 33, and/or a 2-2 fastening portion 34.

The second etching material blocking film 32 may not be etched by the etching material sprayed from the nozzle NZ. In one or more embodiments, the second etching material blocking film 32 may act or serve to block the etching material.

One end of the second etching material blocking film 32 may be fastened to the 2-1 fastening portion 33, and the other end thereof may be fastened to the 2-2 fastening portion 34. The second pressing member 31 may be to press the second etching material blocking film 32 between one end and the other end of the second etching material blocking film 32. In one or more embodiments, the 2-1 fastening portion 33 and the 2-2 fastening portion 34 may act or serve to tightly pull the second etching material blocking film 32 and maintain the tension of the second etching material blocking film 32.

The second pressing member 31 may be closer to the etching target area ECA than the 2-1 fastening portion 33 and the 2-2 fastening portion 34 are each to the etching target area ECA. In one or more embodiments, the second etching material blocking film 32 may be provided to overlap the second etching protection area (for example, IFA2 and NFA2) in plan view. The second etching material blocking film 32 may be provided not to overlap the first etching protection area (for example, IFA1 and NFA1) and the etching target area ECA in plan view.

The second pressing member 31 may relatively move in a direction toward the etching target TG. The second pressing member 31 may relatively move in a direction away from the first etching area selection portion 20. In this way, the second pressing member 31 may be provided to move in one or more suitable directions.

The second pressing member 31 may extend in the first direction DR1. According to one or more embodiments, the second pressing member 31 may include a roller to rotate about the first direction DR1 as a rotation axis. In one or more embodiments, friction between the second pressing member 31 and the second etching material blocking film 32 may be minimized or reduced if (e.g., when) the second pressing member 31 moves in one or more suitable directions.

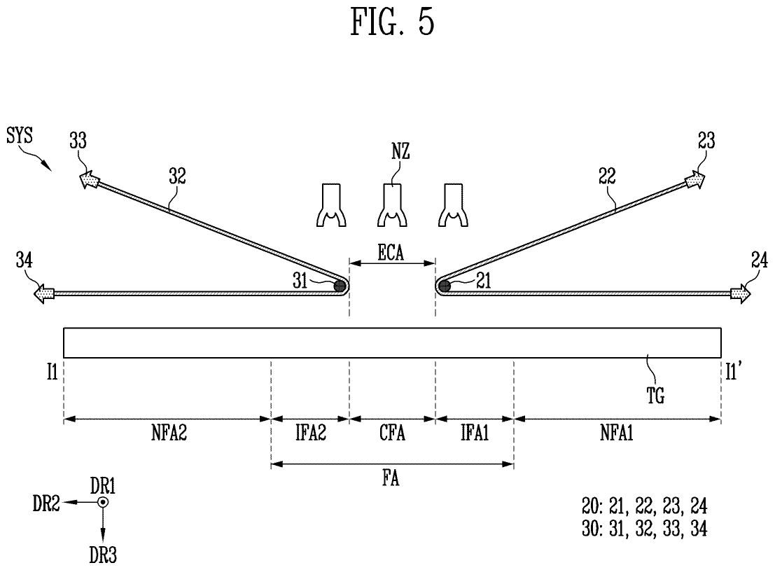

FIGS. 6-10 are views illustrating an etching method using the etching system of FIG. 4.

Referring to FIG. 6, the first operation SS1, the second operation SS2, the third operation SS3, and the fourth operation SS4 may be performed. Hereinafter, the first operation SS1, the second operation SS2, the third operation SS3, and the fourth operation SS4 will be further described with reference to FIGS. 7-10.

Referring to FIG. 7, the first operation SS1 may be performed. In the present operation, the first pressing member 21 and the second pressing member 31 may be relatively moved in a direction toward the etching target TG. In one or more embodiments, the first etching area selection portion 20 may be in contact with the etching target TG at the boundary between the central foldable area CFA and the first in-between foldable area IFA1, and the second etching area selection portion 30 may be in contact with the etching target TG at the boundary between the central foldable area CFA and the second in-between foldable area IFA2.

As shown in FIG. 7, the first etching area selection portion 20 and the second etching area selection portion 30 may be provided not to overlap the central foldable area CFA and to overlap other areas IFA1, IFA2, NFA1, and/or NFA2 excluding the central foldable area CFA. In one or more embodiments, the central foldable area CFA may be referred to as an etching target area. An initial separation distance Di between the first etching area selection portion 20 and the second etching area selection portion 30 may be substantially equal to a width of the central foldable area CFA in the second direction DR2.

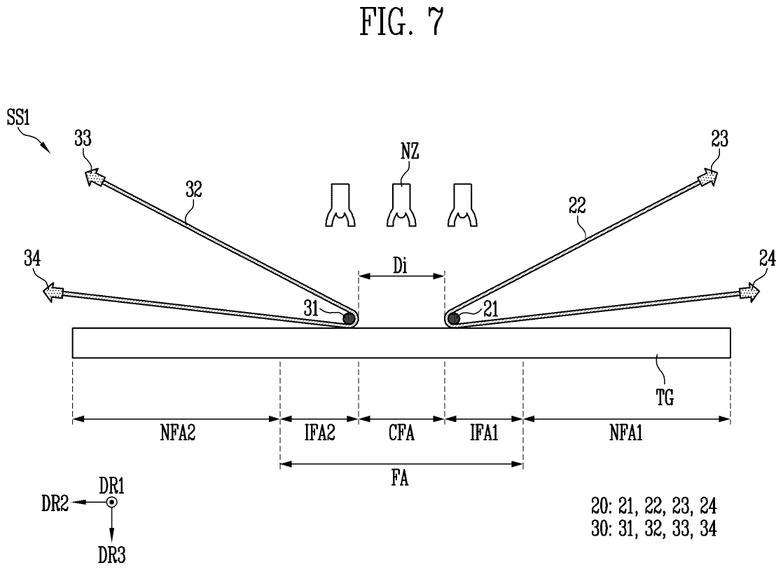

Referring to FIG. 8, the second operation SS2 may be performed. In the present operation, an etching material may be provided from the nozzle NZ. The etching material may be provided to the central foldable area CFA which is an etching target area that does not overlap the first etching area selection portion 20 and the second etching area selection portion 30.

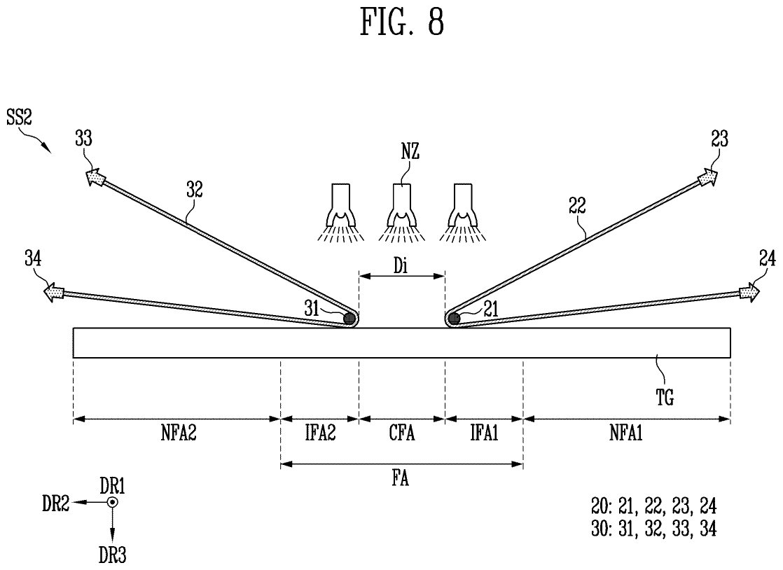

Referring to FIG. 9, the third operation SS3 may be performed. In the present operation, while the etching material is provided from the nozzle NZ, the first etching area selection portion 20 and the second etching area selection portion 30 may be relatively moved in a direction away from each other. In one or more embodiments, an area of the etching target area, which is an area that does not overlap the first etching area selection portion 20 and the second etching area selection portion 30, may increase. In one or more embodiments, areas of the first etching protection area and the second etching protection area, which are areas overlapping the first etching area selection portion 20 and the second etching area selection portion 30, may be reduced.

For example, FIG. 9 is a view illustrating a case in which, as the first etching area selection portion 20 and the second etching area selection portion 30 relatively move, a separation distance between the first etching area selection portion 20 and the second etching area selection portion 30 may increase to an intermediate separation distance D from the initial separation distance Di described with reference to FIG. 7. In one or more embodiments, the etching target area may increase from the central foldable area CFA to the central foldable area CFA and portions of the first in-between foldable area IFA1 and/or the second in-between foldable area IFA2 that are adjacent to the central foldable area CFA.

Referring again to FIGS. 8 and 9, as the second operation SS2 and the third operation SS3 described above are performed, a groove GR, which corresponds to the etching target area of which an area gradually increases, may be formed or provided.

Because the etching target area gradually increases as the first etching area selection portion 20 and the second etching area selection portion 30 move in a direction away from each other, times for which the etching target areas exposed to the etching material may be different (e.g., substantially different). In one or more embodiments, the groove GR may have a differential (e.g., substantially differential) thickness for each area. For example, the groove GR may be formed or provided to have a substantially flat surface in the central foldable area CFA and may be formed or provided to have inclined (e.g., substantially inclined) surfaces in portions of the first in-between foldable area IFA1 and the second in-between foldable area IFA2 that are adjacent to the central foldable area CFA. In one or more embodiments, a thickness THK_GR of the groove GR in the third direction DR3 in the central foldable area CFA may be less than a second thickness THK2 (see FIG. 2).

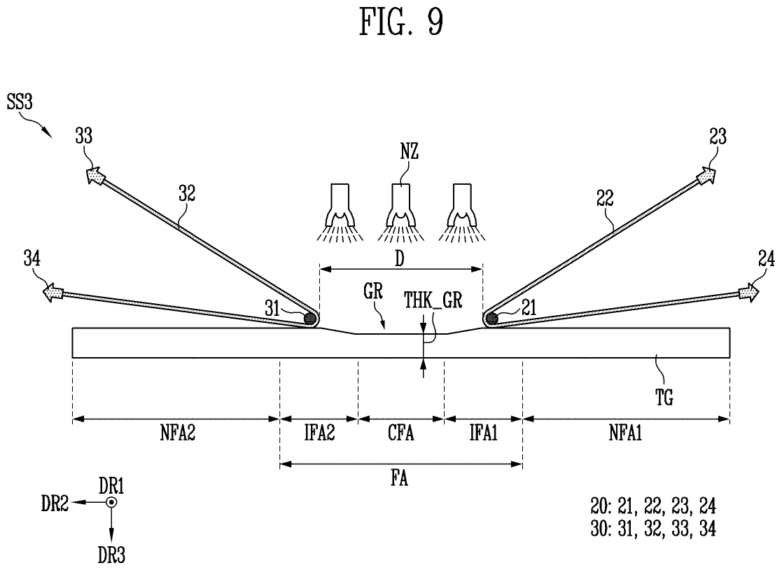

Referring to FIG. 10, the fourth operation SS4 may be performed. In the present operation, a case which a separation distance between the first etching area selection portion 20 and the second etching area selection portion 30 increases from the intermediate separation distance D described with reference to FIG. 9 to a final separation distance Df is shown. In one or more embodiments, the etching target area may increase to a foldable area FA from the central foldable area CFA and portions of the first in-between foldable area IFA1 and the second in-between foldable area IFA2 that are adjacent to the central foldable area CFA.

If (e.g., when) the separation distance between the first etching area selection portion 20 and the second etching area selection portion 30 reaches the final separation distance Df, the nozzle NZ may stop providing the etching material. In one or more embodiments, etching may be ended.

If (e.g., when) the etching is ended, the first etching area selection portion 20 and the second etching area selection portion 30 may be separated from the etching target TG. The groove 100 described with reference to FIG. 2 may be formed or provided in the etching target TG. The etching target TG may be provided as the cover window 1000 described with reference to FIGS. 1 and 2.

Referring again to FIGS. 4-10, the etching method using the etching system SYS of the present disclosure may not use a separate photoresist material and/or the like to etch the etching target TG. In one or more embodiments, costs of an etching process may be reduced, process efficiency may be improved or enhanced, a difficulty of the etching process may be reduced, and one or more defects (for example, over-etching due to residue) caused by the photoresist material may not occur or may be reduced (or a degree or occurrence of one or more defects may be reduced).

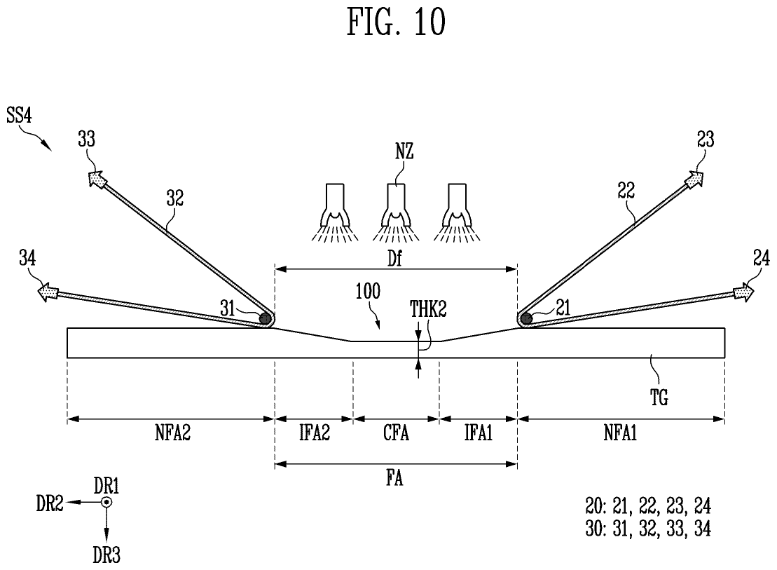

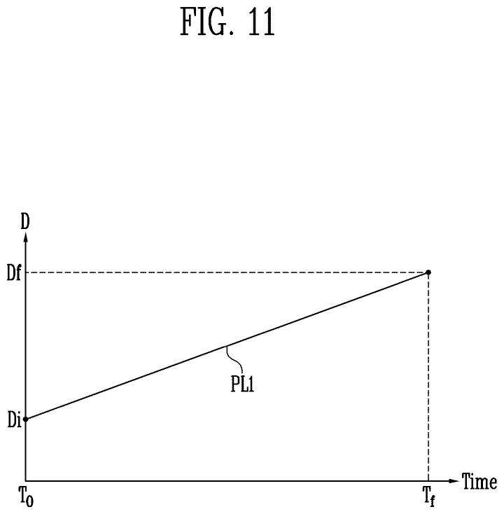

FIGS. 11 and 12 are a graph and a view, respectively, illustrating a first application example of an etching method of the present disclosure.

Referring to FIG. 11, a first graph PL1 is shown. A vertical axis of the first graph PL1 indicates the passage of time, and a horizontal axis indicates a separation distance D between the first etching area selection portion 20 and the second etching area selection portion 30.

An etching start time T₀ may refer to a time at which the etching material starts to be provided from the nozzle NZ in the second operation SS2 described with reference to FIG. 8. At the etching start time T₀, the separation distance D between the first etching area selection portion 20 and the second etching area selection portion 30 may be an initial separation distance Di (see FIG. 8).

An etching end time Tr may refer to a time at which provision of the etching material from the nozzle NZ is ended and etching is ended in the fourth operation SS4 described with reference to FIG. 10. At the etching end time Tr, the separation distance D between the first etching area selection portion 20 and the second etching area selection portion 30 may be a final separation distance Df (see FIG. 10).

From the etching start time T₀ to the etching end time Tt, the separation distance D between the first etching area selection portion 20 and the second etching area selection portion 30 may increase linearly (e.g., substantially linearly) from the initial separation distance Di (see FIG. 8) to the final separation distance Df (see FIG. 10). For example, an amount of change in the separation distance D between the first etching area selection portion 20 and the second etching area selection portion 30 per unit time may be substantially constant.

Referring to FIG. 12, a shape of a groove 100a according to etching conditions of FIG. 11 is shown.

The groove 100a may include a flat surface 110 and/or two inclined surfaces 120a adjacent to the flat surface 110. The flat surface 110 may correspond to one surface 110 of the central foldable area CFA described with reference to FIG. 2. The two inclined surfaces 120a may correspond to one surface 120_1 of the first in-between foldable area IFA1 and one surface 120_2 of the second in-between foldable area IFA2 which have been described with reference to FIG. 2.

The flat surface 110 may have a width W110 in the second direction DR2. The width W110 may be substantially equal to the initial separation distance Di (see FIG. 8). Therefore, the width W110 may be adjusted by adjusting the initial separation distance Di (see FIG. 8).

A second thickness THK2 may be defined in an area in which the flat surface 110 is formed or provided. As a value obtained by subtracting the etching start time T₀ from the etching end time Tr increases, the second thickness THK2 may decrease. For example, if (e.g., when) an etching process time is set to be substantially long, the second thickness THK2 may decrease.

The inclined surface 120a may have a substantially constant inclination. The inclined surface 120a may have a width W120a in the second direction DR2 and a thickness D120a in the third direction DR3. The inclination of the inclined surface 120a may be a value obtained by dividing the thickness D120a by the width W120a.

The width W120a may increase as the final separation distance Df increases. For example, as the final separation distance Df is set to be substantially long, the width W120a may be made substantially large. As the value obtained by subtracting the etching start time T₀ from the etching end time Tr increases, the thickness D120a may increase. For example, if (e.g., when) the etching process time is set to be substantially long, the thickness D120a may increase.

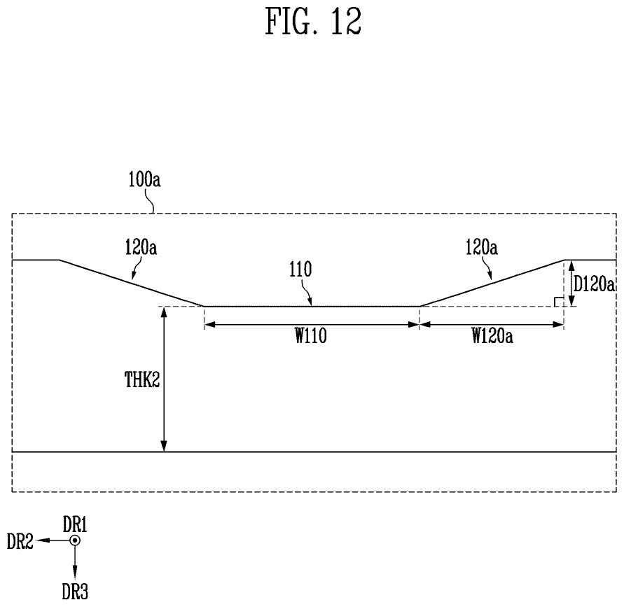

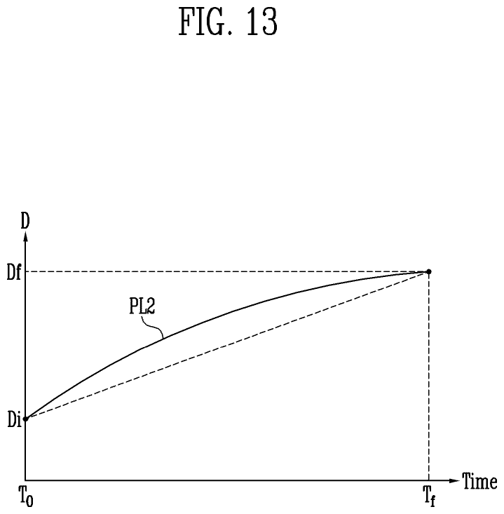

FIGS. 13 and 14 are a graph and a view, respectively, illustrating a second application example of an etching method of the present disclosure.

Hereinafter, the description will be further provided based on differences from the first application example described with reference to FIGS. 11 and 12. Omitted contents will be replaced with the above-described contents.

Referring to FIG. 13, a second graph PL2 is shown. Referring to the second graph PL2, from an etching start time T₀ to an etching end time Tt, an amount of change in a separation distance D between the first etching area selection portion 20 and the second etching area selection portion 30 per unit time may gradually decrease (e.g., may decrease slowly and consistently from the etching start time T₀ to the etching end time Tr in contrast to abrupt, fluctuating, or rapid decrease). For example, the second graph PL2 may have an upward convex shape (e.g., substantially convex shape) as compared to the first graph PL1 described with reference to FIG. 11.

Referring to FIG. 14, a shape of a groove 100b according to etching conditions of FIG. 13 is shown.

The groove 100b may include a flat surface 110 and/or two concave surfaces 120b adjacent to the flat surface 110. The two concave surfaces 120b may correspond to one surface 120_1 of the first in-between foldable area IFA1 and one surface 120_2 of the second in-between foldable area IFA2 which have been described with reference to FIG. 2.

An inclination of the concave surface 120b may gradually increase in a direction away from the flat surface 110. The concave surface 120b may have a width W120b in the second direction DR2 and a thickness W120b in the third direction DR3.

The width W120b may increase as a final separation distance Df increases. For example, as the final separation distance Df is set to be substantially long, the width W120b may be made substantially large. As a value obtained by subtracting the etching start time T₀ from the etching end time Tr increases, the thickness D120b may increase. For example, if (e.g., when) an etching process time is set to be substantially long, the thickness D120b may increase.

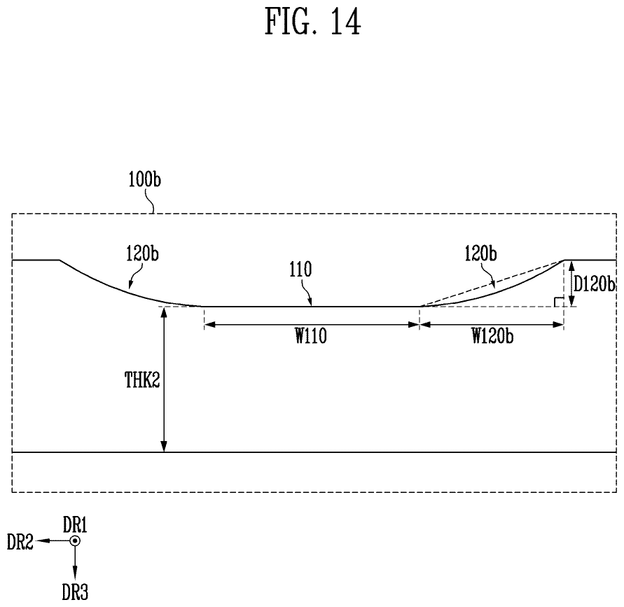

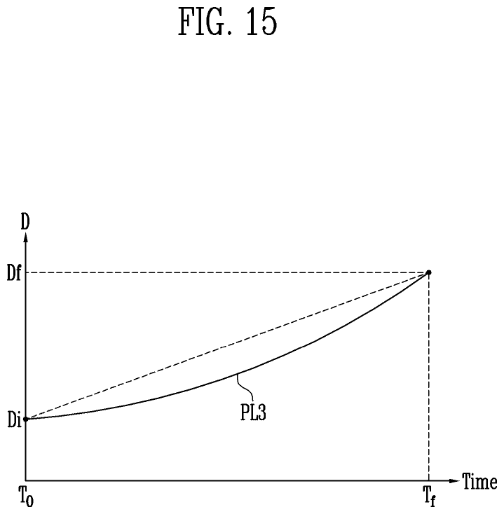

FIGS. 15 and 16 are a graph and a view, respectively, illustrating a third application example of an etching method of the present disclosure.

Hereinafter, the description will be further provided based on differences from the first application example described with reference to FIGS. 11 and 12. Omitted contents will be replaced with the above-described contents.

Referring to FIG. 15, a third graph PL3 is shown. Referring to the third graph PL3, from an etching start time T₀ to an etching end time Tt, an amount of change in a separation distance D between the first etching area selection portion 20 and the second etching area selection portion 30 per unit time may gradually increase (e.g., may increase slowly and consistently from the etching start time T₀ to the etching end time Tr in contrast to abrupt, fluctuating, or rapid increase). For example, the third graph PL3 may have a downward concave shape (e.g., substantially concave shape) as compared to the first graph PL1 described with reference to FIG. 11.

Referring to FIG. 16, a shape of a groove 100c according to etching conditions of FIG. 15 is shown.

The groove 100c may include a flat surface 110 and/or two convex surfaces 120c adjacent to the flat surface 110. The two convex surfaces 120c may correspond to one surface 120_1 of the first in-between foldable area IFA1 and one surface 120_2 of the second in-between foldable area IFA2 which have been described with reference to FIG. 2.

An inclination of the convex surface 120c may gradually decrease in a direction away from the flat surface 110. The convex surface 120c may have a width W120c in the second direction DR2 and a thickness W120c in the third direction DR3.

The width W120c may increase as a final separation distance Df increases. For example, as the final separation distance Df is set to be substantially long, the width W120c may be made substantially large. As a value obtained by subtracting the etching start time T₀ from the etching end time Tt increases, the thickness D120c may increase. For example, if (e.g., when) an etching process time is set to be substantially long, the thickness D120c may increase.

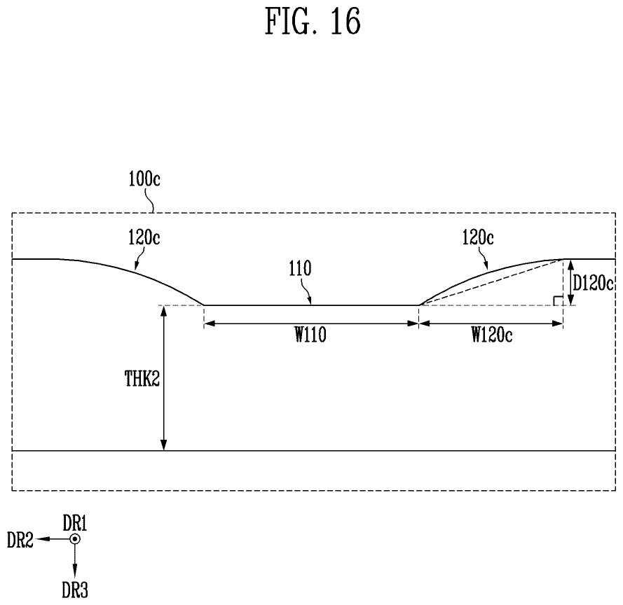

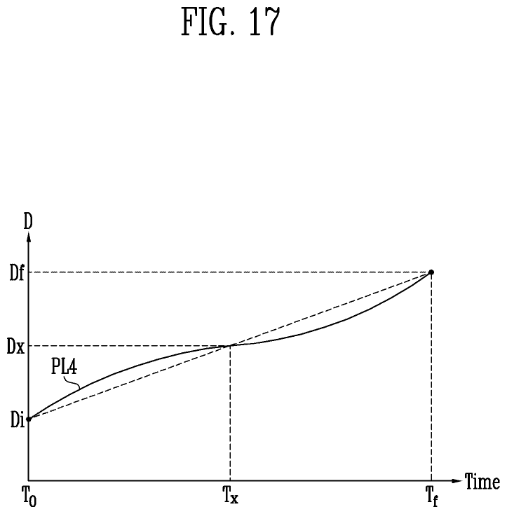

FIGS. 17 and 18 are a graph and a view, respectively, illustrating a fourth application example of an etching method of the present disclosure.

Hereinafter, the description will be further provided based on differences from the first application example described with reference to FIGS. 11 and 12. Omitted contents will be replaced with the above-described contents.

Referring to FIG. 17, a fourth graph PL4 is shown. Referring to the fourth graph PL4, from an etching start time T₀ to an etching middle time Tx, an amount of change in a separation distance D between the first etching area selection portion 20 and the second etching area selection portion 30 per unit time may gradually decrease, and from an etching middle time Tx to an etching end time Tt, an amount of change in the separation distance D between the first etching area selection portion 20 and the second etching area selection portion 30 per unit time may gradually increase. For example, as compared to the first graph PL1 described with reference to FIG. 11, the second graph PL4 may have an upward convex shape (e.g., substantially convex shape) in a section from the etching start time T₀ to the etching middle time Tx and may have a downward concave shape (e.g., substantially concave shape) in a section from the etching middle time Tx to the etching end time Tt.

Referring to FIG. 18, a shape of a groove 100d according to etching conditions of FIG. 17 is shown.

The groove 100d may include a flat surface 110 and/or two curved surfaces 120d adjacent to the flat surface 110. The two curved surfaces 120d may correspond to one surface 120_1 of the first in-between foldable area IFA1 and one surface 120_2 of the second in-between foldable area IFA2 which have been described with reference to FIG. 2.

An inclination of the curved surface 120d may gradually increase and then gradually decrease in a direction away from the flat surface 110. The curved surface 120d may have a width W120d in the second direction DR2 and a thickness W120d in the third direction DR3.

The width W120d may increase as a final separation distance Df increases. For example, as the final separation distance Df is set to be substantially long, the width W120d may be made substantially large. As a value obtained by subtracting the etching start time T₀ from the etching end time Tr increases, the thickness D120d may increase. For example, if (e.g., when) an etching process time is set to be substantially long, the thickness D120d may increase.

Referring again to FIGS. 11-18, in the etching method using the etching system SYS of the present disclosure, the grooves 100a, 100b, 100c, and 100d having one or more suitable shapes may be formed or provided according to one or more suitable etching conditions shown in the first graph PL1, the second graph PL2, the third graph PL3, and the fourth graph PL4. As such, according to the etching method using the etching system SYS of the present disclosure, grooves having one or more suitable shapes may be easily formed or provided as compared to an etching process using a separate photoresist material.

According to an etching system and an etching method using the etching system of the present disclosure, a separate photoresist material and/or the like may not be used to etch an etching target. In one or more embodiments, costs of an etching process may be reduced, process efficiency may be improved or enhanced, a difficulty of the etching process may be reduced, and one or more defects (for example, over-etching due to residue) caused by a photoresist material may not occur or may be reduced (or a degree or occurrence of one or more defects may be reduced).

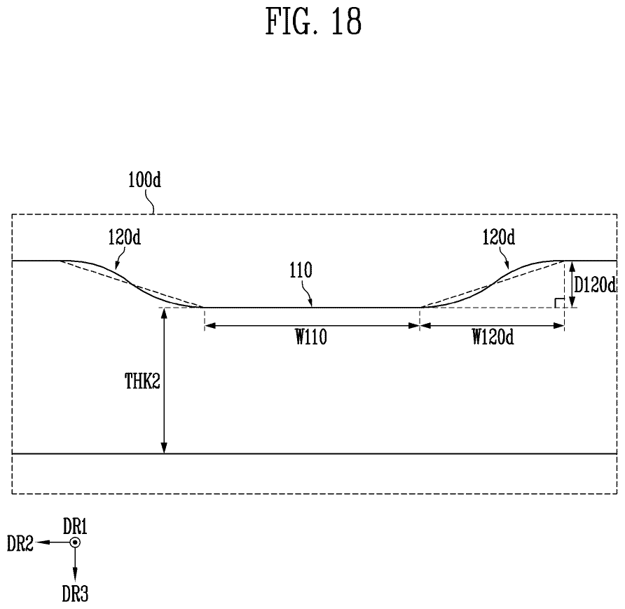

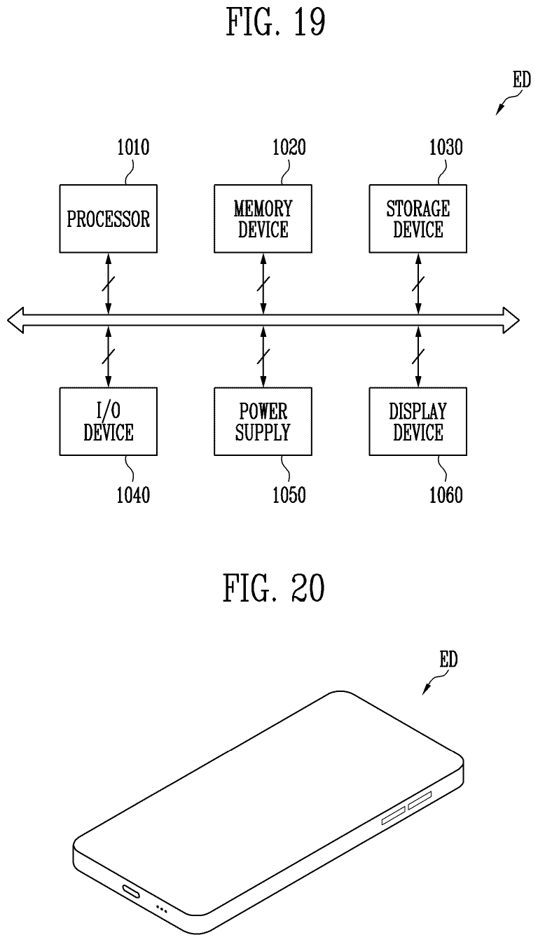

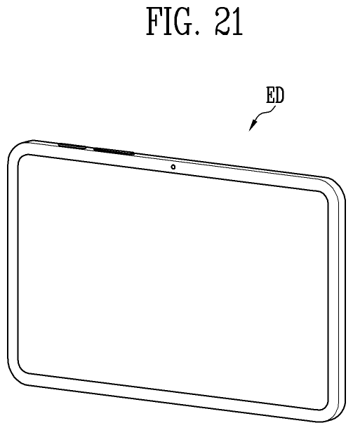

FIG. 19 is a schematic block diagram illustrating an electronic device including a display device according to one or more embodiments. FIG. 20 is a schematic diagram illustrating an example where the electronic device of FIG. 19 is a smartphone. FIG. 21 is a schematic diagram illustrating an example where the electronic device of FIG. 19 is a tablet computer.

Referring to FIGS. 19-21, an electronic device ED may include a processor 1010, a memory device 1020, a storage device 1030, an input/output (I/O) device 1040, a power supply 1050, and a display device 1060. The display device 1060 may be the display device DD of FIG. 3A or FIG. 3B. The electronic device ED may further include one or more ports for communication with a video card, a sound card, a memory card, a USB device, or other system. In one or more embodiments, as illustrated in FIG. 20, the electronic device ED may be a smartphone. In one or more embodiments, as illustrated in FIG. 21, the electronic device ED may be a tablet computer. However, the aforementioned examples are illustrative, and the electronic device ED is not necessarily limited to the aforementioned examples. For example, the electronic device ED may be a cellular phone, a video phone, a smart pad, a smartwatch, a navigation device for vehicles, a computer monitor, a laptop computer, a head-mounted display device, and/or the like.

The processor 1010 may be to perform specific (e.g., set or predetermined) calculations or tasks. In one or more embodiments, the processor 1010 may be a microprocessor, a central processing unit, an application processor, and/or the like. The processor 1010 may be connected to other components through an address bus, a control bus, a data bus, and/or the like. In one or more embodiments, the processor 1010 may be connected to an expansion bus, such as a peripheral component interconnect (PCI) bus. In one or more embodiments, the processor 1010 may be to provide input image data to the display device 1060. Hence, the display device 1060 may display an image based on the input image data provided from the processor 1010.

The memory device 1020 may be to store data desired or needed to perform the operation of the electronic device ED. The memory device 1020 may be to function as a working memory and/or a buffer memory for the processor 1010. For example, the memory device 1020 may include one or more volatile memory devices, such as a dynamic random access memory (DRAM) device, a static random access memory (SRAM) device, and a mobile DRAM device.

The storage device 1030 may be to store data in response to control signals or data from the processor 1010. The storage device 1030 may include one or more non-volatile storages to retain the data even if (e.g., when) the electronic device ED is powered off. In one or more embodiments, the storage device 1030 may include a solid state drive (SSD), a hard disk drive (HDD), a CD-ROM, and/or the like.

The I/O device 1040 may include input devices, such as a keyboard, a keypad, a touchpad, a touch screen, and/or a mouse, and output devices, such as a speaker and/or a printer. In one or more embodiments, the display device 1060 may be integrated with the I/O device 1040.

The power supply 1050 may be to supply power desired or needed to perform the operation of the electronic device ED. For example, the power supply 1050 may include a power management integrated circuit (PMIC). In one or more embodiments, the power supply 1050 may be to supply power to the display device 1060.

The display device 1060 may be to display images in response to control signals or data from the processor 1010. The display device 1060 may be connected to other components through the buses or other communication links.

A display device, a device for manufacturing the same and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

In the context of the present disclosure and unless otherwise defined, the terms “use,” “using,” and “used” may be considered synonymous with the terms “utilize,” “utilizing,” and “utilized,” respectively.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

While the subject matter of the present disclosure has been described with reference to certain embodiments, it will be understood by those skilled in the art that one or more suitable changes and modifications may be made without departing from the spirit and scope of the present disclosure as defined by the appended claims and equivalents thereof.

Accordingly, the technical scope of the present disclosure may be determined by on the technical scope of the accompanying appended claims and equivalents thereof.

What is claimed is:

1. An etching system, comprising:
an etching target comprising a first etching protection area, a second etching protection area, and an etching target area between the first etching protection area and the second etching protection area;
a nozzle to provide an etching material toward the etching target;
a first etching area selection portion which is between the etching target and the nozzle and overlaps the first etching protection area in plan view; and
a second etching area selection portion which is between the etching target and the nozzle and overlaps the second etching protection area in plan view,
wherein the first etching area selection portion and the second etching area selection portion are relatively movable in a direction away from each other.

2. The etching system as claimed in claim 1, wherein the etching target area does not overlap the first etching area selection portion and the second etching area selection portion in plan view.

3. The etching system as claimed in claim 1, wherein the first etching area selection portion is in contact with the etching target at a boundary between the first etching protection area and the etching target area, and
the second etching area selection portion is in contact with the etching target at a boundary between the second etching protection area and the etching target area.

4. The etching system as claimed in claim 1, wherein the first etching area selection portion comprises:
a 1-1 fastening portion and a 1-2 fastening portion;
a first etching material blocking film having one end fastened to the 1-1 fastening portion and the other end fastened to the 1-2 fastening portion; and
a first pressing member to press the first etching material blocking film between the one end and the other end of the first etching material blocking film.

5. The etching system as claimed in claim 4, wherein, in plan view, the first pressing member is closer to the etching target area than the 1-1 fastening portion and the 1-2 fastening portion are each to the etching target area.

6. The etching system as claimed in claim 4, wherein the second etching area selection portion comprises:
a 2-1 fastening portion and a 2-2 fastening portion;
a second etching material blocking film having one end fastened to the 2-1 fastening portion and the other end fastened to the 2-2 fastening portion; and
a second pressing member to press the second etching material blocking film between the one end and the other end of the second etching material blocking film.

7. The etching system as claimed in claim 6, wherein, in plan view, the second pressing member is closer to the etching target area than the 2-1 fastening portion and the 2-2 fastening portion are each to the etching target area.

8. The etching system as claimed in claim 6, wherein each of the first pressing member and the second pressing member extends in a first direction.

9. The etching system as claimed in claim 8, wherein each of the first pressing member and the second pressing member comprises a roller to rotate about the first direction as a rotation axis.

10. The etching system as claimed in claim 6, wherein the first etching material blocking film overlaps the first etching protection area in plan view, and
the second etching material blocking film overlaps the second etching protection area in plan view.

11. The etching system as claimed in claim 10, wherein the first etching material blocking film does not overlap the second etching protection area and the etching target area in plan view, and
the second etching material blocking film does not overlap the first etching protection area and the etching target area in plan view.

12. An etching method utilizing an etching system, the etching method comprising providing an etching material from a nozzle and simultaneously and relatively moving a first etching area selection portion and a second etching area selection portion in a direction away from each other,
wherein the etching system comprises:
an etching target comprising a first etching protection area, a second etching protection area, and an etching target area between the first etching protection area and the second etching protection area;
the nozzle to provide the etching material toward the etching target;
the first etching area selection portion which is between the etching target and the nozzle and overlaps the first etching protection area in plan view; and
the second etching area selection portion which is between the etching target and the nozzle and overlaps the second etching protection area in plan view.

13. The etching method as claimed in claim 12, wherein, as the first etching area selection portion and the second etching area selection portion relatively move in the direction away from each other, an area of the etching target area increases.

14. The etching method as claimed in claim 12, wherein, as the first etching area selection portion and the second etching area selection portion relatively move in the direction away from each other, an area of each of the first etching protection area and the second etching protection area decreases.

15. The etching method as claimed in claim 12, wherein, in the relatively moving of the first etching area selection portion and the second etching area selection portion in the direction away from each other, an amount of change in separation distance between the first etching area selection portion and the second etching area selection portion per unit time is constant.

16. The etching method as claimed in claim 12, wherein, in the relatively moving of the first etching area selection portion and the second etching area selection portion in the direction away from each other, an amount of change in separation distance between the first etching area selection portion and the second etching area selection portion per unit time gradually increases.

17. The etching method as claimed in claim 12, wherein, in the relatively moving of the first etching area selection portion and the second etching area selection portion in the direction away from each other, an amount of change in separation distance between the first etching area selection portion and the second etching area selection portion per unit time gradually decreases.

18. The etching method as claimed in claim 12, wherein, in the relatively moving of the first etching area selection portion and the second etching area selection portion in the direction away from each other, an amount of change in separation distance between the first etching area selection portion and the second etching area selection portion per unit time gradually decreases and then gradually increases.

19. The etching method as claimed in claim 12, wherein, in the relatively moving of the first etching area selection portion and the second etching area selection portion in the direction away from each other, the first etching area selection portion is in contact with the etching target at a boundary between the first etching protection area and the etching target area, and the second etching area selection portion is in contact with the etching target at a boundary between the second etching protection area and the etching target area.

20. An electronic device, comprising:
a processor to provide input image data; and
a display device to display an image based on the input image data, the display device comprising a cover window,
wherein the cover window comprises: a first non-foldable area, a second non-foldable area, and a foldable area between the first non-foldable area and the second non-foldable area,
wherein the foldable area comprises: a central foldable area, a first in-between foldable area between the central foldable area and the first non-foldable area, and a second in-between foldable area between the central foldable area and the second non-foldable area,
wherein the cover window is manufactured according to the etching method utilizing the etching system as claimed in claim 12.
